(19) United States
(12) Patent Application Publication
(10) Pub. No.: US 2007/0018186 A1
(43) Pub. Date: Jan. 25, 2007

(54) Light emitting diode device having advanced light extraction efficiency and preparation method thereof

(75) Inventors: Bu Gon Shin, Yuseong-gu (KR); Min Ho Choi, Pohang-si (KR); Duk Sik Ha, Cheongju-si (KR); Min A. Yu, Yuseong-gu (KR); Jong Hoon Kang, Seoul (KR); Jae Seung Lee, Daedeok-gu (KR); Hyun Woo Shin, Gwacheon-si (KR)

Correspondence Address: MCKENNA LONG & ALDRIDGE LLP, 1900 K STREET, NW, WASHINGTON, DC, 20006, US

(73) Assignee: LG Chem, Ltd., Seoul (KR)

(21) Appl. No.: 11/488,183

(22) Filed: Jul. 18, 2006

(30) Foreign Application Priority Data
Jul. 19, 2005 (KR) 2005-65236
Aug. 19, 2005 (KR) 2005-76336
Oct. 25, 2005 (KR) 2005-100669
Oct. 25, 2005 (KR) 2005-100691
Oct. 27, 2005 (KR) 2005-101758

(51) Int. Cl. H01L 33/00; H01L 21/00

(52) U.S. Cl. 257/98; 438/27; 257/E33.074

(57) ABSTRACT

Disclosed is an LED device, a method for manufacturing the same, and a light emitting apparatus having the same. The LED device includes (a) a light emitting diode unit and (b) an adjustment layer laminated on a light emitting surface of the light emitting diode unit, a fine pattern having being formed on the adjustment layer by repeating a shape in a light emission direction. The adjustment layer is (i) at least one layer formed by aligning transparency adjustment particles having a shape or (ii) a polymer film layer having a fine pattern imprinted on the polymer film layer so as to adjust transparency. A fine pattern adjustment layer having various shapes and an adjustable size is introduced on the light emitting surface of the LED unit. As a result, the light extraction efficiency of the surface of the LED unit improves together with ease of manufacturing and secured uniformity.

This application claims the benefit of Korean Patent Application Nos. 10-2005-0065236, 10-2005-0076336, 10-2005-0100669, 10-2005-0100691, 10-2005-0101758, filed Jul. 19, 2005, Aug. 19, 2005, Oct. 25, 2005, Oct. 25, 2005 and Oct. 27, 2005, respectively in Korea, which are hereby incorporated by reference in their entirety for all purposes as if fully set forth herein.

### TECHNICAL FIELD

The present invention relates to a light emitting diode device having a fine pattern adjustment layer which has various shapes and an adjustable size, instead of protrusions and indentations obtained through an etching process affecting electrodes physically and chemically, in order to guarantee easy fabrication and uniformity and improve the light extraction efficiency, as well as a method for manufacturing the same.

### BACKGROUND ART

As generally known in the art, a light emitting diode (LED) device is a kind of PN junction semiconductor devices, which emits light when current is applied thereto in a forward direction.

The LED device using a semiconductor can efficiently covert electric energy into light and has a long life span of about 5 to 10 years, so the LED device may reduce power consumption and costs for repair and maintenance thereof. For this reason, the LED device has been spotlighted in a field of next-generation illumination appliances.

In general, the LED is fabricated by sequentially growing an n-type layer, an active layer (light emitting layer), and a p-type layer on a sapphire substrate. At this time, the n-type layer, the active layer, and the p-type layer are made from III-V group compounds, such as GaAs, GaP, GaN, InP, InAs, GaAlN, InGaN, InAlGaN, or a mixture thereof.

In this way, a sapphire substrate is mainly used to grow III-V group compound semiconductors for the manufacture of an LED. Since the sapphire substrate is an insulating material, a negative electrode and a positive electrode of the LED are formed on the upper side of a wafer.

In order to fabricate a low-power gallium nitride-based LED device, a sapphire substrate, on which a diode crystal structure is grown, is mounted on a lead frame and two electrodes are connected to an upper portion of the sapphire substrate (see FIG. 1). At this time, in order to improve a heat dissipation efficiency, the sapphire substrate is thinned to a thickness of about 100 μor less and then attached to the lead frame. However, since the sapphire substrate has thermal conductivity of about 50 W/mK, the sapphire substrate represents high heat-resistance even if the sapphire substrate has a thickness less than 100 micron.

On the contrary, in a case of a high-power gallium nitride-based LED device, there is a tendency to mainly use a flip chip bonding scheme in order to further improve the heat dissipation characteristics. According to the flip chip bonding scheme, a chip having an LED structure is turned over and attached to a sub-mount having superior thermal conductivity, such as a silicon wafer (thermal conductivity: 150 W/mK) or an AlN ceramic substrate (thermal conductivity: about 180 W/mK) (see FIG. 2). In this case, heat is dissipated through the sub-mount so that the heat dissipation efficiency can be improved as compared with when heat is dissipated through the sapphire substrate. However, the flip chip bonding scheme cannot provide a satisfactorily sufficient heat dissipation efficiency and the procedure to fabricate the LED device by the flip chip bonding scheme is complicated.

In order to solve the above problems, a laser lift-off scheme has been recently suggested for fabricating the LED device. According to the laser lift-off scheme, laser is irradiated onto a sapphire substrate, on which an LED structure has been grown, thereby separating the sapphire from a GaN LED crystalline structure, and then a packaging process is carried out (see FIG. 3). The LED device fabricated through the above laser lift-off scheme may provide superior heat dissipation efficiency and remarkably reduces fabrication processes thereof. In addition, a light emission area of the LED is substantially identical to the size of a chip (in a case of the flip chip, a light emitting area corresponds to about 60° % of a chip size), so the LED device can provide superior characteristics.

However, an LED device fabricated through the above laser lift-off scheme exhibits a light extraction efficiency lower than those of LED devices fabricated using the above-described technologies. The cause of this is as follows: The fabrication of the LED device through the above laser lift-off scheme is completed by covering an LED structure, in which a sapphire substrate is lifted-off by laser irradiation, with a molding material such as epoxy or a molding material having fluorescent materials mixed therewith. At this time, a considerable fraction of light generated from the LED structure is not emitted outward, but is totally reflected to progress toward the LED structure again and then fade away due to a large difference between refractive indices of the GaN and the molding material. Assuming that the refractive index of the GaN is about 2.6 and the refractive index of the molding material is about 1.5, the amount of light totally reflected at an interface between the two materials is about 91%, so the light extraction efficiency leaves much to be desired.

To solve this, research is being pursued on a new method in which the sapphire substrate is removed by laser irradiation and then protrusions and indentations are provided on an exposed n-type GaN layer in a stage before or after electrode wiring is formed. In a specific method for providing protrusions and indentations on the n-type GaN surface, conical-shaped protrusions and indentations are formed on the n-type GaN surface by a wet etching process (cf. T. Fujii et al., Appl. Phys. Lett., 2004, 84, 855; Y. Gao et al., Jap. J. Appl. Phys., 2004, 43, L637) . In this case, it has been confirmed that the light extraction efficiency is enhanced about twice.

FIG. 4 illustrates paths of light generated in a

conventional laser lift-off (LLO) type LED. More specially, FIG. 4a schematically shows that only partial light emerges from the LLO-type LED due to the total reflection occurring at a surface of the LED, and FIG. 4b schematically shows that the light extraction efficiency of the LED is enhanced by roughing the LED surface after the laser lift-off.

However, such a process of providing protrusions and indentations on the LED surface has disadvantages in that it requires additional wet etching and the size of protrusions and indentations is limited to the thickness of the n-type GaN layer.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is a sectional structural view of a low-power gallium nitride-based light emitting diode (LED) device;

FIG. 2 is a sectional structural view of a high-power flip chip gallium nitride-based LED device;

FIG. 3 is a schematic view showing processes of fabricating a gallium nitride-based LED device by a laser lift-off scheme;

FIG. 4 is a schematic view showing paths of light generated in a conventional LLO-type LED;

FIG. 5a is a schematic view showing light paths when spherical transparency adjustment particles form an aligned adjustment layer on a light emitting surface of an LED unit according to an embodiment of the present invention;

FIG. 5b is a schematic view showing light paths when triangular pyramid-shaped or conical transparency adjustment particles form an aligned adjustment layer on a light emitting surface of an LED unit according to an embodiment of the present invention;

FIGS. 6a to 6c are schematic views showing light paths when a polymer film adjustment layer is provided with an imprinted fine pattern having the shape of a triangular pyramid, a quadrangular pyramid, and a cone, respectively, according to an embodiment of the present invention; and

FIGS. 7a to 7d are schematic views showing a series of processes for manufacturing a polymer film having a fine pattern imprinted thereon according to the present invention.

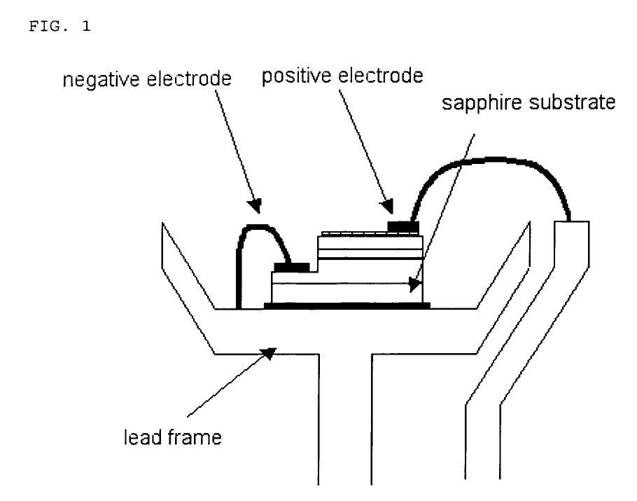

### DISCLOSURE OF THE INVENTION

The present invention has been made to improve the low light extraction efficiency of conventional LEDs and solve the problem of limited size of protrusions and indentations formed by conventional wet etching processes.

It is an object of the present invention to provide an LED device having a transparency adjustment layer, which is provided with a fine pattern, so that the surface structure of an LED unit is adjusted by the layer and the light extraction efficiency is improved, as well as a method for manufacturing the same.

According to an aspect of the present invention, there is provided a light emitting diode device, a method for manufacturing the same, and a light emitting apparatus having the same. The light emitting diode device includes (a) a light emitting diode unit and (b) an adjustment layer laminated on a light emitting surface of the light emitting diode unit, a fine pattern having being formed on the adjustment layer by repeating a shape in a light emission direction, wherein the adjustment layer is (i) at least one layer formed by aligning transparency adjustment particles having a shape or (ii) a polymer film layer having a fine pattern imprinted on the layer so as to adjust transparency.

In accordance with another aspect of the present invention, there is provided a polymer film or substrate with or without transparency adjustment particles, including (a) a film or substrate having a fine pattern imprinted on a surface so as to adjust a surface structure of a light emitting diode unit, the film or substrate containing a polymer or the polymer and transparency adjustment particles, and (b) a polymer film with no fine pattern or a release film removably attached to a surface of the substrate.

The present invention will now be described in detail.

When light is incident on a medium with a small refractive index from a medium with a large one, the refractive angle is generally larger than the incident angle and, at a specific incident angle, the refractive angle becomes 90° and total reflection occurs. The incident angle in this case is referred to as a critical angle and, when the incident angle of light becomes larger than the critical angle, light undergoes total reflection at the interface.

An LED device having a molding portion (e.g. epoxy with a refractive index of 1.5) formed on a flat LED unit (e.g. GaN with a refractive index of 2.6) emits light outwards. The critical angle of emitted light is about 35.2° . This means that light emitted from the LED unit at an angle larger than 35.2° undergoes total reflection. In an attempt to avoid the total reflection, it has been proposed to form a fine pattern, particularly protrusions and indentations, on the light emitting surface of the LED unit. In this case, even when the first reflection of light falls within the total reflection range, the light can avoid total reflection after two or more times of reflection. This improves the light extraction efficiency.

In order to reduce the amount of light totally reflected inwards, it has been attempted to form protrusions and indentations on a surface of the LED unit by performing wet etching directly to the surface. However, this approach has a problem in that, after the protrusions and indentations are formed, metal components of electrodes are corroded out, or the surface condition of the electrodes varies and degrades the performance. In addition, the fact that etching is conducted in the crystal direction of the n-type layer makes it impossible to form a fine pattern in a desired shape and limits the size of protrusions and indentations to the thickness of n-type GaN. Furthermore, irradiation of UV rays during etching of the n-type layer makes the equipment complicated and lengthens the process time.

Accordingly, the present invention aims at reducing the internal total reflection of light emitted from the LED device and improving the light extraction efficiency thereby. To this end, an adjustment layer, which has a fine pattern formed thereon in a predetermined shape, is introduced on a light emitting surface of the LED unit. The adjustment layer is made of transparency adjustment particles having a predetermined shape. Alternatively, a polymer film adjustment layer, the surface of which has been roughened so as to form a fine pattern, is separately introduced on the light emitting surface of the LED unit.

As such, the present invention can fundamentally solve the problems occurring in the prior art, i.e. problems resulting from direct etching of a flat surface of the LED unit, or direct application of heat or pressure to the LED unit.

More particularly, use of an adjustment layer made of transparency adjustment particles with a predetermined shape or a polymer film adjustment layer, which has a fine pattern formed thereon before introduction on a surface of the LED unit, according to the present invention enables mass production, guarantees uniformity of the fine pattern, and provides easy modification of the line width and/or depth of respective elements of the fine pattern, as well as the thickness. By providing protrusions and indentations on a surface of the LED unit in various shapes and sizes, it is possible to reduce the amount of light totally reflected at the surface and increase the light extraction efficiency remarkably.

In addition, the adjustment layer having a fine pattern formed thereon is fabricated in a process separate from a process for forming the LED unit and is then attached to the light emitting surface of the LED unit. This simplifies the overall manufacturing process and reduces the processing time, compared with a case of etching the n-type layer. This is particularly advantageous to easiness of manufacturing and mass productivity if a pattern is formed on a large scale in advance and cut into separate patterns, which are attached to desired surfaces.

The adjustment layer (b) introduced on the light emitting surface of the LED unit according to the present invention is made of a transparent material and defines a region through which light from the light emitting surface of the LED passes. The adjustment layer may have a predetermined shape. Alternatively, the adjustment layer is made of a material, on which a fine pattern can be easily formed, so that the adjustment layer can be attached to the LED unit with a fine pattern formed thereon in a separate process. As used herein, transparency refers to the properties of a material capable of transmitting visible rays without absorbing them.

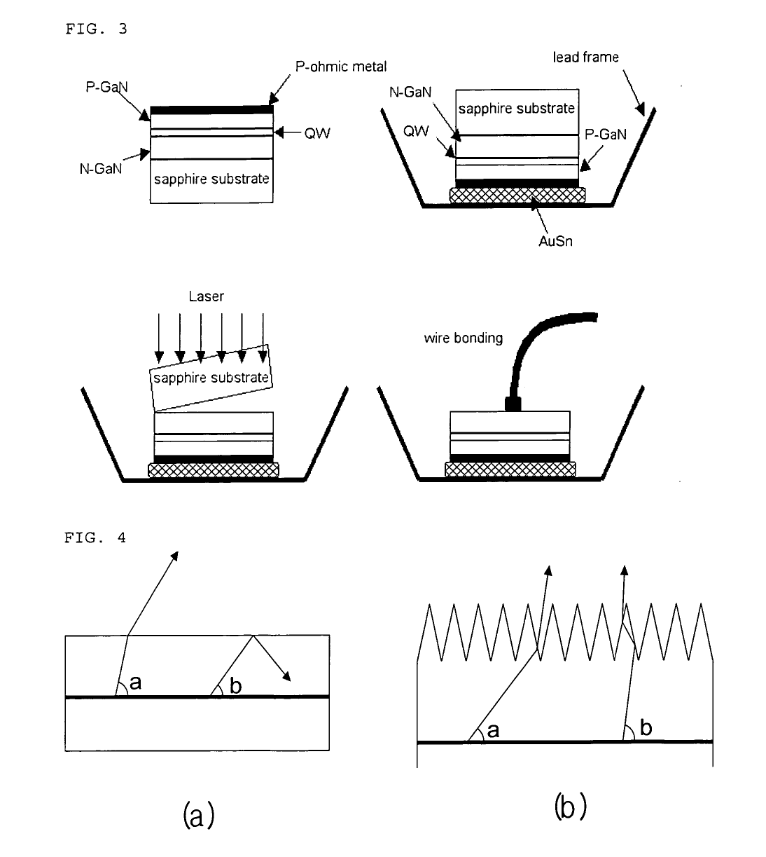

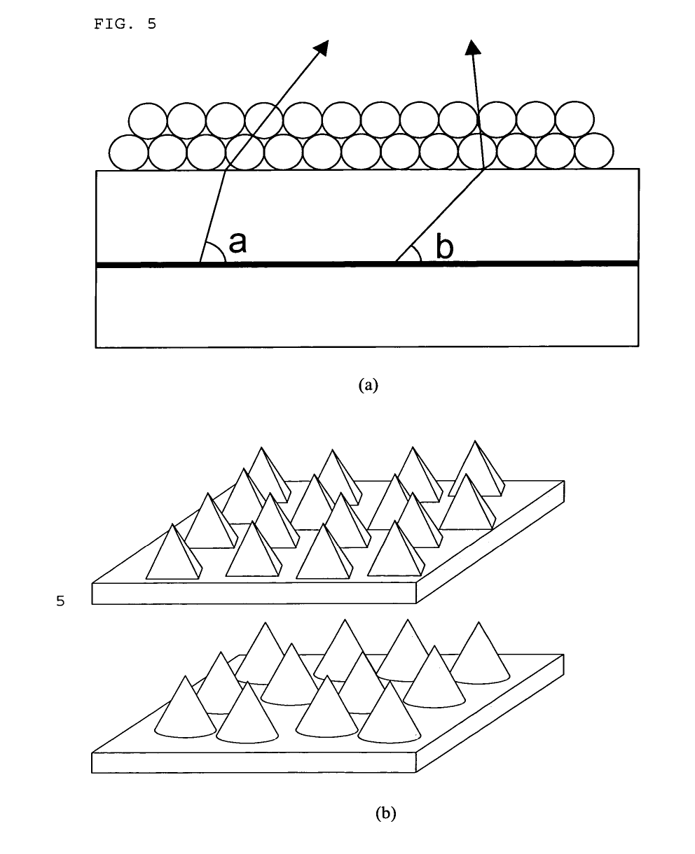

The shape or pattern of the adjustment layer is not limited as long as it increases the light extraction efficiency. For example, the adjustment layer may have the shape of spheres, cones, triangular pyramids, or polyhedrons with least four faces, as shown in FIGS. 5a and 5b. The shape of quadrangular pyramids is particularly preferred due to increased light extraction from the front surface of the LED. The ratio d/w of depth d to line width w of respective elements of the pattern formed on the adjustment layer is preferably increased as much as possible, in order to obtain a larger effective critical angle and improve the light extraction efficiency thereby. For sufficient increase in the light extraction efficiency, the ratio d/w is preferably 1 or more.

As mentioned above, a critical angle α₀, i.e. an incident angle causing total reflection, is determined by the refractive indices of two materials through which light passes. When the refractive indices of both materials are n₁ and n₂ (n₁>n₂), respectively, the critical angle α₀ is obtained from the relationship: sin α₀=n₂/n₁. By reducing the difference in refractive index between both materials, it is possible to increase the incident angle and reduce the amount of light totally reflected. In general, the refractive index of the peripheral portion (e.g. molding portion) of the LED unit is substantially smaller than that of the surface thereof. This means that, in order to improve the light extraction, the refractive index I of an adjustment layer introduced on the light emitting surface of the LED unit is preferably larger than that of the peripheral portion (or molding portion) thereof. More preferably, refractive index of the molding portion<refractive index I of the adjustment layer≦refractive index of the LED unit±0.8.

The degree of increase in the light extraction efficiency of the adjustment layer is affected by the thickness of the adjustment layer. If the thickness is too small, the frequency of internal total reflection increases. This adversely affects the light extraction efficiency. Therefore, the thickness of the adjustment layer is preferably in the range of 500-10,000 μm. However, the numeral value is not limited to that in the present invention.

Two embodiments of the adjustment layer according to the present invention will now be described, however, it is to be noted that the scope of the present invention is not limited to that.

According to a first embodiment of the adjustment layer, transparency adjustment particles are used to form the adjustment layer. Preferably, transparency adjustment particles having a predetermined shape are aligned so as to form at least one fine pattern layer. More preferably, transparency adjustment particles having the shape of spheres, cones, triangular pyramids, or polyhedrons with at least four faces are used to form a single layer.

The size of the transparency adjustment particles is not limited in a specific manner and, for example, may be in the range of 10 nm to 100 μm. When the particle size is smaller than half the light emission wavelength (λ/2), i.e. in the case of nano-scale particles, the effective refractive index of molding material increases. This reduces the degree of total reflection. When the particle size is larger than half the light emission wavelength (λ/2), i.e. in the case of micro-scale particles, the resulting scattering increases the efficiency of light emission to the outside. The latter case (i.e. particle size>λ/2) is preferred.

The transparency adjustment particles may have the shape of spheres, cones, triangular pyramids, or polyhedrons with at least four faces, as mentioned above. The shape of triangular pyramids or cones is particularly preferred because the area attached to the LED unit is increased, thereby improving the light extraction efficiency.

The transparency adjustment particles may be made of metal oxide, non-limiting examples of which include titanium, tungsten, zinc, aluminum, indium, and tin-based oxide. An LED made of gallium nitride (GaN) has a very high refractive index of about 2.4 and, in this case, transparency adjustment particles preferably have a refractive index of 2.0-2.4 for the sake of efficient light extraction. For example, titanium oxide has a refractive index of 2.4 and is suitable for the LED made of gallium nitride. Instead of metal oxide, at least one of blue, green, yellow, and red phosphors may be used with or without white particles.

The first embodiment of the adjustment layer (i), which is composed of transparency adjustment particles, may be manufactured in one of the conventional methods. A preferred method for manufacturing the adjustment layer includes the steps of (a) preparing a dispersion or paste by dispersing transparency adjustment particles or the particles and a binder into a solution, (b) applying the dispersion or paste to a light emitting surface of an LED unit, and (c) removing the solvent or the solvent and the binder.

The step of (c) removing the solvent and the binder may be replaced with a step of (d) drying the paste after the transparency adjustment particles are deposited on the light emitting surface of the LED unit.

Non-limiting examples of the solvent include methanol, ethanol, and water. Preferably, the solvent has good dispersion properties so that transparency adjustment particles can be easily dispersed therein. In addition, the solvent should be easily applied to a surface of the LED unit and easily removed at a low temperature. In general, a solvent can be removed by boiling it above its boiling point. When a very volatile solvent is used, it can be removed at a lower temperature, because it can evaporate below its boiling point.

Non-limiting examples of the binder include cellulose, polyurethane, and acrylic. When one of these is used as the binder, it can be removed by increasing the temperature above its decomposition temperature. These materials are removed at a temperature of 200° C or higher. If necessary, the solvent and the binder may not be removed, as mentioned above.

According to a second embodiment of the adjustment layer, a transparent polymer is used to form a polymer film adjustment layer having a fine pattern formed thereon. The layer may be formed by imprinting polymer slurry, which has been applied to a substrate. Alternatively, a polymer substrate may be directly imprinted so as to form the layer.

The size of respective elements of the fine pattern formed on the polymer film adjustment layer is not limited in a specific manner and, for example, may be in the range of 10 nm to 100 μm. When the size is smaller than half the light emission wavelength (λ/2), the effective refractive index of molding material increases, thereby reducing the degree of total reflection, as mentioned above. When the size is larger than half the light emission wavelength (λ/2) the resulting scattering increases the efficiency of light emission to the outside. The latter case (i.e. size>λ/2) is preferred.

The polymer film layer is formed by hardening a UV-curable or heat-curable polymer material, non-limiting examples of which include epoxy resin, urea resin, phenolic resin, silicon resin, and acrylic resin.

The polymer film adjustment layer may contain transparency adjustment particles. To this end, transparency adjustment particles are mixed with a liquid polymer paste, which is translucent in the visible ray range, at a high density. The particles are then subjected to imprint shaping so as to form a transparency adjustment fine pattern.

The refractive index I of the polymer film adjustment layer containing the transparency adjustment particles lies between the refractive index of the transparency adjustment particles and that of the polymer material, and the effective refractive index is determined from that range. Most preferably, the effective refractive index is the same as that of the LED unit, e.g. gallium nitride. In order to minimize the scattering of light inside the transparency adjustment layer, the size of metal oxide particles must be smaller than half the wavelength of light emitted from the LED (i.e. 2/λ), and the smaller the size is, the lesser the scattering becomes. The size of transparency adjustment portions of the fine pattern, which is composed of metal oxide and polymer mixture, must be larger than half the wavelength of light emitted from the LED (i.e. 2/λ), and the larger the size is, the higher the efficiency of light emission from the surface becomes. As such, the transparent fine pattern, which includes metal oxide particles, provides a combined action of an effective refractive index effect, which is based on the size of the transparent particles, and a scattering effect, which is based on the size and shape of the fine pattern. This provides a synergy effect of minimized internal total reflection of emitted light and improved light extraction efficiency.

In order to obtain the effective refractive index effect, the size of transparency adjustment particles is preferably smaller than half the light emission wavelength (λ/2), i.e. nano-scale size. The size of respective elements of the fine pattern formed on the polymer film adjustment layer, which includes transparency adjustment particles, is preferably larger than half the light emission wavelength (λ/2) so that light is scattered strongly.

The polymer film adjustment layer having a fine pattern formed thereon according to the present invention may be manufactured in one of conventional methods. A preferred method for manufacturing the polymer film adjustment layer includes the steps of (a) applying a slurry, which contains a transparent polymer, to a substrate; (b) compressing a surface of the substrate, to which the slurry has been applied, by using a stamp having a fine pattern carved on its surface; (c) shaping a fine pattern by means of hardening based on UV rays or heat and separating a film, on which a fine pattern has been imprinted, from the stamp; and (d) attaching a polymer film, on which the fine pattern has been imprinted, to a light emitting surface of an LED unit.

When the transparent polymer is mixed with transparency adjustment particles, the resulting polymer film adjustment layer has a fine pattern imprinted thereon with the transparency adjustment particles contained in the pattern.

The stamp is made of a material through which UV rays can pass, such as quartz, glass, sapphire, and diamond, or a material having high thermal conductivity, such as silicon-based material.

The polymer slurry applied to the substrate contains a polymer, such as PMMA (polymethylmethacrylate) and a solvent. The solvent resolves other components so that the polymer slurry is endowed with coating properties, and the viscosity is adjusted according to the amount of use.

Non-limiting examples of the solvent which can be used in the present invention include acetone; methyl ethyl ketone; methyl isobutyl ketone; methyl cellosolve; ethyl cellosolve; tetrahydrofuran; 1,4-dioxane; ethylene glycol dimethylether; ethylene glycol diethylether; propylene glycol dimethylether; propylene glycol diethylether; chloroform; methylene chloride; 1,2-dichloroethane; 1,1,1-trichloroethane; 1,1,2-trichloroethane; 1,1,2-trichloroethene; 1,2,3-trichloroethane hexane; heptane; octane; cyclopentane; cyclohexane; benzene; toluene; xylene; methanol; ethanol; isopropanol; propanol; butanol; tert-butanol; propylene glycol monomethylether; propylene glycol monoethylether; propylene glycol monopropylether ;propylene glycol monobutylether; dipropylene glycol dimethylether; dipropylene glycol diethylether; dipropylene glycol monomethylether; methyl carbitol; ethyl carbitol; propyl carbitol; butyl carbitol; cyclopentanone; cyclohexanone; propylene glycol methyletheracetate; propylene glycol ethyletheracetate; propylene glycol methylether propionate; 3-methoxybutyl acetate; 3-methyl-3-methoxybutyl acetate; ethyl-3-ethoxypropionate; ethyl cellosolveacetate; methyl cellosolveacetate; butyl acetate; propyl acetate; and ethyl acetate. One of these components or a mixture of at least two of them may be used. Considering viscosity adjustment, 60-90 weight parts, preferably 65-85 weight parts, of solution is used per a total of 100 weight parts of polymer slurry.

Non-limiting examples of a UV-curable or heat-curable polymer substrate, which is to be imprinted, include PET (polyethylene terephthalate), PC (polycarbonate), PES (polyethersulfone), and PEN (polyethylene naphthalate).

When the polymer film layer is obtained by imprinting a film on a substrate (e.g. silicon wafer) by using a UV-transparent or heat-curable stamp, it is difficult to handle the film because its thickness is too small. Therefore, when a polymer substrate is used instead of the polymer film, the processes for coating the silicon substrate with a polymer film, imprinting it, and removing the film from the substrate can be omitted. This is advantageous in terms of mass production. Preferably, an anti-adhesion material (e.g. silicon-base release agent) is applied to protrusions and indentations of the stamp so that the stamp can be easily separated after UV-based or heat-based hardening.

The polymer film or substrate, which has been imprint-patterned as mentioned above, may be supplied to an LED manufacturer as a roll or substrate with an adhesive and a protective film applied thereto. After receiving the film or substrate, the manufacturer can cut it into a desired size, remove the protective film, and attach the film or substrate on top of a manufactured LED. If necessary, the film or substrate may be cut into a desired size and delivered to the manufacturer.

According to another embodiment, a method for manufacturing a polymer film adjustment layer having a fine pattern imprinted thereon or a film adjustment layer containing a polymer and transparency adjustment particles includes the steps of (a) preparing a transparent polymer substrate with or without transparency adjustment particles; (b) compressing a surface of the substrate by using a stamp having a fine pattern carved on a surface; (c) shaping a fine pattern by means of hardening based on UV rays or heat so that the fine pattern is imprinted on a surface of the substrate; and (d) attaching the substrate to a light emitting surface of a light emitting diode unit, the substrate having the fine pattern imprinted on the surface or containing the polymer and the transparency adjustment particles.

The film or substrate may be a polymer film or substrate with or without transparency adjustment particles and may include (a) a film or substrate having a fine pattern imprinted on a surface so as to adjust a surface structure of a light emitting diode unit, the film or substrate containing a polymer or a polymer and transparency adjustment particles, and (b) a polymer film with no fine pattern or a release film removably attached to a surface of the substrate.

Hereinafter, preferred embodiments of the present invention will be described with reference to the accompanying drawings. The foregoing and other objects, features, and advantages of the present invention will become more apparent from the following detailed description.

FIGS. 5a and 5b show light paths when transparency adjustment particles form an aligned adjustment layer on a light emitting surface of an LED unit according to a first embodiment of the present invention.

When an adjustment layer is formed on the light emitting surface of the LED unit as shown, the effective refractive index of the peripheral portion (e.g. molding portion) near the surface of the LED unit is increased by the transparency adjustment particles. The spatial distribution of the effective refractive index depends on the distribution of the particles and, in turn, causes light from the LED unit to undergo irregular refraction at the interface with the peripheral portion (e.g. molding material), which includes the transparency adjustment particles. This spatially varies the refractive angle. Such a change of the effective refractive index reduces internal total reflection resulting from the difference in refractive index between the surface portion of the LED unit and the peripheral portion (e.g. molding material) and improves the light extraction efficiency. The difference in refractive index is particularly small in regions where the transparency adjustment particles make contact with each other or with the LED unit. In this case, total reflection barely occurs, and the light extraction efficiency increases substantially.

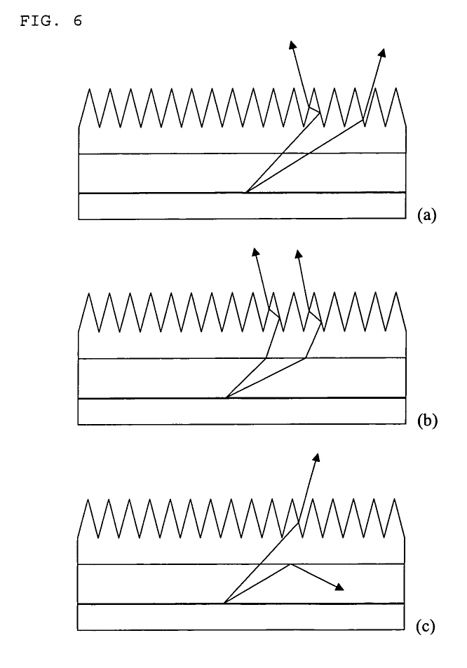

FIGS. 6a to 6c show light paths when a transparent polymer film adjustment layer (second embodiment) having a fine pattern imprinted thereon or a polymer film adjustment layer including transparency adjustment particles is introduced on a light emitting surface of an LED unit according to the present invention.

When the refractive index of an adopted polymer film layer is equal to (refer to FIG. 6a) or larger than (refer to FIG. 6b) that of the surface of the LED, no light is totally reflected at the surface of the LED. The degree of total reflection of light resulting from the difference in refractive index between the polymer film and the peripheral portion (e.g. molding material) is reduced by the fine pattern imprinted on the polymer film.

When the refractive index of an adopted polymer film is smaller than that of the light emitting portion of the LED unit and larger than that of the peripheral portion (e.g. molding material), as shown in FIG. 6c, the difference in refractive index between the surface of the LED unit and the polymer film is smaller than that between the surface of the LED unit and the peripheral portion. This reduces the amount of totally reflected light. The degree of total refection of light resulting from the difference in refractive index between the polymer film and the peripheral portion (e.g. molding material) is reduced by the fine pattern imprinted on the polymer film. When an adjustment layer including transparency adjustment particles is used as the polymer film layer, the combined action of the effective refractive index effect and the optical scattering effect substantially increases the light extraction efficiency, as mentioned above.

The LED device according to the present invention may be manufactured in a conventional method, except for the fact that an adjustment layer having a fine pattern formed therein is introduced on a surface of an LED unit, preferably to a light emitting surface thereof. For example, a sapphire substrate, on which an LED crystal structure has grown, is mounted on a sub-mount; the sapphire substrate is removed by laser irradiation; and electrodes are formed and connected to an external power supply.

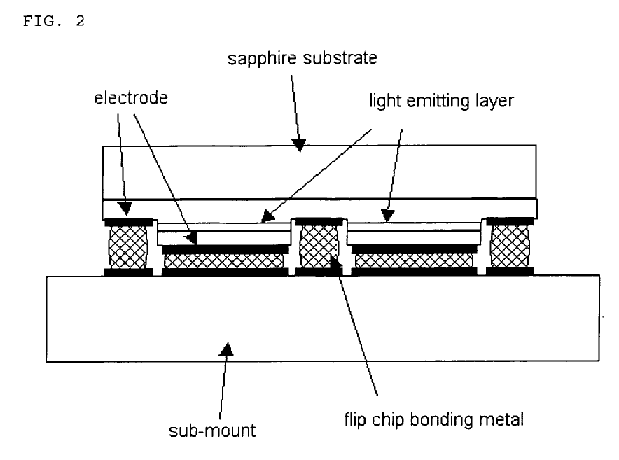

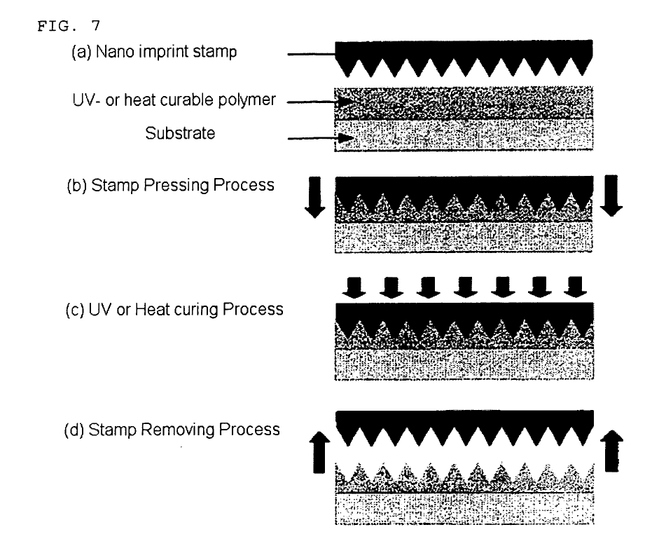

A method for manufacturing an LED device according to the present invention will now be described with special emphasis on a step for providing an adjustment layer having a fine pattern formed thereon as a clear distinction from conventional methods. FIG. 3 shows an overall manufacturing process employing a laser liftoff mode, and FIGS. 7a to 7d show an example of a method for manufacturing a transparent polymer film adjustment layer having a fine pattern imprinted thereon.

(1) Step of Growing a Light Emitting Diode Unit on a Sapphire Substrate

A sapphire substrate (b) formed on one surface thereof with a light emitting part can be used without limitations. For instance, an n-type layer, an active layer (light emitting layer) and a p-type layer are sequentially grown from the sapphire substrate 10 through a metal organic chemical vapor deposition (MOCVD) process, etc.

The light emitting part grown from the sapphire substrate may include the n-type layer, the active layer and the p-type layer, which are made from GaN based compounds generally known in the art. For instance, a non-limitative example of the compounds includes GaN, GaAlN, InGaN, InAlGaN, or a mixture thereof. In addition, the active layer (light emitting layer) has a single quantum well structure or a multiple quantum well (MQW) structure. Besides the n-type layer, the active layer and the p-type layer, a buffer layer can be provided. It is possible to fabricate the light emitting diodes having various wavelengths from short wavelength to long wavelength by controlling components of the GaN compounds. As a result, not only a blue nitride-based light emitting diode having the wavelength of 460 nm, but also various light emitting diodes can be used.

(2) Step of Forming the P-type Ohmic Contact Layer

After cleaning a wafer including the sapphire substrate having the LED structure (for example, a GaN LED), the p-type ohmic contact layer is formed on a surface of the p-type layer (for example, a p-type GaN layer) provided at an upper portion of the wafer through a vacuum deposition process by using a metal. Then, the heat treatment process is performed for the p-type ohmic contact layer.

(3) Step of Polishing the Surface of the Sapphire Substrate

general, the LED crystal structure is grown on the sapphire substrate having a thickness of about 430 gm. In order to form a mirror surface so that laser beams can easily pass through the sapphire substrate, the thickness of the sapphire is reduced to about 80-100 μm, if necessary, through a lapping/polishing process.

(4) Step of Creating a Bond With a Substrate (sub-mount)

If necessary, for example in case of a high-power LED device, the sub-mount substrate can be used in order to improve the heat dissipation efficiency. That is, the above-polished sapphire substrate having LED structure thereon is turned over so that the polished surface of the sapphire substrate faces upward. Then, the p-type ohmic contact layer of the LED is bonded to the sub-mount substrate by using an adhesive material.

The sub-mount substrate may be made of a conductive or non-conductive material, non-limiting examples of which include metal (e.g. CuW, Al, Cu), Si wafer, and ceramic (e.g. AlN, Al₂O₃).

(5) Step of Forming the Unit Chip

If necessary, the sub-mount substrate and the light emitting diode crystal structure may be diced into unit LED chips. Typical methods generally known in the art, such as dicing, scribing and breaking processes, can be performed in order to separate the unit chips. In addition, it is also possible to irradiate laser beam so as to separate the unit chips.

(6) Step of Attaching the Unit Chips to a Lead Frame

The unit chips are attached to a lead frame. If necessary, the sub-mount substrate bonding step and/or the unit chip forming step may be omitted, and the p-type ohmic contact metal surface of the LED unit may be attached to the lead frame with an adhesive (e.g. AuSn).

As used herein, the lead frame refers to a package used to fabricate a final LED lamp, and any type of LED package, including the lead frame, falls within the scope of the present invention. According to an alternative embodiment, a sapphire substrate having a LED crystal structure grown thereon is cut into unit chips, which are attached to a lead frame, not to a sub-mount substrate, and the sapphire substrate is removed.

(7) Step of Laser Irradiation

Non-limiting examples of a method for removing the sapphire substrate include laser irradiation (e.g. eximer laser irradiation). For example, when the sapphire surface of unit chips are irradiated with laser beams so that sapphire substrates are removed one by one, the sapphire substrates are removed from at least one chip by each laser beam. In this case, the crystal structure within the unit chips remains intact. To this end, the unit chips must be positioned away from the edge of regions irradiated with laser beams.

Preferably, the wavelength of laser beams is in the range of 200 nm-365 nm so as to exhibit energy higher than the energy gap of gallium nitride.

After passing through the sapphire substrate, laser beams are absorbed by gallium nitride. As a result, gallium nitride at the interface between sapphire and gallium nitride decomposes into metal gallium and nitrogen gas. As such, the sapphire substrate is separated from the LED crystal structure.

(8) Step of Forming N-type Ohmic Contact Metal

If necessary, n-type ohmic contact metal is formed on the n-type surface (e.g. n-type GaN), which has been exposed by removal of the sapphire substrate, by using a combination of Ti, Cr, Al, Sn, Ni, Au, etc in a vacuum deposition process.

(9) Step of Forming and Introducing an Adjustment layer having a fine pattern formed thereon

An adjustment having a fine pattern formed thereon, as mentioned above, is introduced on the light emitting surface of the LED unit. If necessary, the introduction of the adjustment layer may be preceded by a wire bonding step.

(10) Step of Bonding Wires

Gold wires are bonded to the n-type surface and/or the p-type surface after partially exposing the adjustment layer having a fine pattern formed thereon.

(11) Step of Treating a Molding Material

A molding material such as epoxy or a molding material mixed with a fluorescent substance is coated to complete the fabrication of the light emitting diode device. At this time, it is possible to properly change the order of the step of forming the unit chip in order to promote facilitation and simplification of the fabrication method.

The above-mentioned embodiments of the fabricating method of the light emitting diode device are only preferred examples, and the present invention should not be limited to them.

Although it has been assumed in the above description that the gallium nitride-based LED crystal structure on the sapphire substrate is subjected to laser liftoff, the manufacturing method, output type, and emission range of the LED device according to the present invention are not limited in a specific manner as long as an adjustment pattern having a fine pattern formed thereon is created on the light emitting surface of the LED unit. Particularly, use of laser liftoff for fabrication of an LED device is advantageous in that the resulting device is free of any problem resulting from a high refractive index of the GaN LED, which has an n-type GaN layer positioned on its top.

In addition, the present invention provides a light emitting unit with a light emitting diode device which has the above-mentioned structure or is manufactured by the above-mentioned method. The light emitting unit includes all kinds of light emitting unit having a light emitting diode device, for example, an illuminator, an indicating unit, a sterilizer lamp, a display unit and so forth.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

Best Mode for Carrying Out the Invention

Reference will now be made in detail to the preferred embodiments of the present invention. It is to be understood that the following examples are illustrative only and the present invention is not limited thereto.

Embodiment 1

A sapphire substrate having a GaN-based LED structure grown thereon is initially cleaned, and nickel and silver are deposited on a p-type GaN surface by using electron beams so as to form ohmic contact metal. The deposited metal is subjected to rapid heat treatment in order to realize ohmic contact. For laser liftoff, the sapphire substrate is lapped to a thickness of 100 μm and polished. The resulting substrate is cut into a size of 1 mm×1 mm and attached to a lead frame by using silver paste. A KrF laser is used to emit light having a wavelength of 248 nm at an intensity of 600 mJ/cm² so that the sapphire substrate is removed from the LED. Gold wires are bonded to a GaN surface, which has been exposed after removal of the sapphire substrate. When the completed LED is subjected to a brightness test at a current of 300 mA, the measurement result is 26.1 mW.

After the measurement, gold wires are bonded to the same LED, and a solution is applied to the front of the exposed GaN surface. The solution contains 30% of titanium oxide particles, which have an anatase phase and a diameter of about 50 nm, dispersed in methanol. The solvent is then removed to form a particle-applied layer having a thickness of 1000 nm. When the LED is subjected to a brightness test at a current of 300 mA, the measurement result is 32.4 mW, which is about 25% larger than the former result (i.e. 26.1 mW) without the titanium oxide particle layer.

Although no molding material is used in Embodiment 1, it can be assumed that there exists a molding material having the same refractive index of air (i.e. 1). That is, it can be inferred from the result of Embodiment 1 that the transparent particle adjustment layer improves the light extraction efficiency even when a molding material exists.

Embodiment 4

An LED is manufactured in the same method as in the case of Embodiment 1, except that an imprinted polymer film adjustment layer replaces the titanium oxide particles.

A method for forming an imprinted polymer pattern on a silicon wafer, as shown in FIGS. 7a to 7d, will now be described. The line width and height of the pattern are varied from tens of nanometers to hundreds of nanometers, respectively, in order to obtain an optimum condition. An imprint master is fabricated by subjecting a silicon substrate to wet etching. The silicon substrate is spin-coated with photoresist and exposed to light two times, after rotating it by 90° every time, based on a laser interference technique using an Ar⁺ icon laser. When the silicon substrate is developed, a photoresist pattern is obtained at an interval of 200 nm. The silicon wafer is subjected to wet etching in KOH solution by using the obtained photoresist pattern. The resulting silicon imprint master has an interval of 200 nm and a height of 120 nm. In order to obtain a polymer pattern, the silicon substrate is spin-coated with PC (polycarbonate) having a refractive index of 1.59 and dried so that a film is formed to a thickness of 1.5 μm. The resulting PC film and the silicon imprint master are positioned to face each other and, by using nano imprint equipment Nanosis 620 available from NND Inc., they are compressed under a pressure of 20 bar at a temperature of 160° C. They are then cooled at a temperature of 1000° C. or lower and separated. The resulting pattern on the PC film matches the inverse image of the silicon imprint master. The imprint polymer film fabricated in this manner is cut into the LED device size with a wafer processing apparatus, i.e. scribing and breaking equipment, and is attached to an LED device with epoxy by using a flip chip bonding apparatus. When the completed LED is subjected to a brightness test at a current of 300 mA, the measurement result is 33.5 mW, which is about 36% larger than the former result (i.e. 26.1 mW) without the imprinted polymer film.

Embodiment 5

An LED is manufactured in the same method as in

the case of Embodiment 4, except that an imprinted polymer substrate replaces the imprinted polymer film. When the completed LED is subjected to a brightness test at a current of 300 mA, the measurement result is 32 mW, which is very similar to the result of Embodiment 4. This shows that Embodiment 5, which uses a polymer substrate, is more advantageous than Embodiment 4 in terms of mass production.

Embodiment 6

A sapphire substrate having a GaN-based LED structure grown thereon is initially cleaned, and nickel and silver are deposited on a p-type GaN surface by using electron beams so as to form ohmic contact metal. The deposited metal is subjected to rapid heat treatment in order to realize ohmic contact. Peripheral regions of the substrate, which are to be cut into unit LEDs, are subjected to dry etching so as to remove the light emitting surface. This is for the purpose of preventing current leakage from the peripheral surface during scribing and breaking processes at a later time. For laser liftoff, the sapphire substrate is lapped to a thickness of 100 μm and polished. The resulting substrate is cut into a size of 1 mm×1 mm in conformity with a portion defined by dry etching, and is attached to a 2-inch silicon sub-mount substrate by using AuSn. The sub-mount substrate has negative and positive electrode pads formed thereon in advance so that they are connected to n-ohmic and p-ohmic contacts of the LED, respectively. At least 100 LED chips are periodically arranged at an interval of 0.5 mm. Each LED is irradiated with light having a wavelength of 248 mm at an intensity of 600 mJ/cm² by using an eximer laser. Then, Ti/Al-based metal is vacuum-deposited on an n-type GaN surface, which has been exposed by removal of the sapphire substrate, and is subjected to rapid heat treatment so that n-type ohmic contact is provided. In order to form a negative wire bonding portion on the sub-mount substrate, a negative wire bonding pad portion on the sub-mount substrate is electrically connected to n-ohmic contact metal on the LED surface by using Au as an interconnection metal layer. A silicon oxide layer is formed beneath the interconnection metal layer for electrical insulation from the LED. The sub-mount substrate is diced so that it is cut into sub-mount chips, each of which has a unit LED chip attached thereto. The sub-mount chips are attached to a lead frame by using AuSn, and the negative and positive electrode pads on the sub-mount are connected to the negative and positive electrodes of the lead frame by means of Au wire bonding, respectively. After epoxy molding, the device is completed. When the fabricated LED is subjected to a brightness test at a current of 300 mA, the measurement result is 91 mW.

In order to confirm the improvement of light extraction efficiency resulting from a fine structure formed by imprinting a mixture of metal oxide particles and epoxy, a fine structure is formed before dicing the sub-mount. Particularly, metal oxide (TiO₂ powder) is mixed with a liquid epoxy resin at a volume ratio of 7:3. The mixture is screen-printed on a sub-mount substrate, which is provided with an LED, and imprinted as shown in FIGS. 7a to 7d so that quadrangular pyramids are solely formed in the LED surface region. It is to be noted that the negative and positive electrode pad portions of the sub-mounted substrate are exposed so that wire binding can be performed thereto. The sub-mount substrate is cut into unit sub-mount chips, which are attached to a lead frame. After wire bonding and molding, the LED is completed. When the LED device is subjected to an optical output test at an operating current of 300 mA, the measurement result is 118 mW, which is about 30% larger than the result without the imprinted fine structure.

### INDUSTRIAL APPLICABILITY

As can be seen from the foregoing, according to the present invention, a separate adjustment layer having a fine pattern formed thereon adjusts the surface structure of an LED unit. This substantially improves the light extraction efficiency of the surface of the LED unit.

1. A light emitting diode device comprising:
(a) a light emitting diode unit and
(b) an adjustment layer laminated on a light emitting surface of the light emitting diode unit, a fine pattern having being formed on the adjustment layer by repeating a shape in a light emission direction, wherein the adjustment layer is
(i) at least one layer formed by aligning transparency adjustment particles having a shape or
(ii) a polymer film layer having a fine pattern imprinted on the polymer film layer so as to adjust transparency.

2. The light emitting diode device as claimed in claim 1, wherein the adjustment layer has a refractive index larger than a refractive index of a molding portion introduced on the light emitting diode unit.

3. The light emitting diode device as claimed in claim 1, wherein each pattern element formed on the adjustment layer has a shape of a sphere, a cone, or a polyhedron with at least four faces.

4. The light emitting diode device as claimed in claim 1, wherein a ratio d/w of depth d to line width w of each pattern element formed on the adjustment layer is equal to or larger than 1.

5. The light emitting diode device as claimed in claim 1, wherein the adjustment layer has a thickness of 500-10,000 mm.

6. The light emitting diode device as claimed in claim 1, wherein the adjustment layer (i) is a single layer formed by transparency adjustment particles having a shape of a sphere, a cone, or a polyhedron with at least four faces.

7. The light emitting diode device as claimed in claim 1, wherein the transparency adjustment particles are at least one kind of metal oxide selected from the group consisting of titanium, tungsten, zinc, aluminum, indium, and tin oxide.

8. The light emitting diode device as claimed in claim 1, wherein the transparency adjustment particles comprise white particles or at least one kind of phosphor selected from the group consisting of blue phosphor, green phosphor, yellow phosphor, and red phosphor.

9. The light emitting diode device as claimed in claim 1, wherein the transparency adjustment particles have a size of 10 nm-100 μm.

10. The light emitting diode device as claimed in claim 1, wherein the adjustment layer (ii) is formed by hardening a UV-curable or heat-curable polymer.

11. The light emitting diode device as claimed in claim 10, wherein the UV-curable or heat-curable polymer is at least one kind of resin selected from the group consisting of epoxy resin, urea resin, phenolic resin, silicon resin, and acrylic resin.

12. The light emitting diode device as claimed in claim 1, wherein the adjustment layer (ii) contains transparency adjustment particles inside the polymer film layer.

13. The light emitting diode device as claimed in claim 12, wherein a polymer film adjustment layer containing the transparency adjustment particles is obtained by compressing a mixture of the transparency adjustment particles and a transparent polymer with a stamp having a fine pattern carved on a surface and curing the mixture with UV rays or heat so that a fine pattern is imprinted.

14. The light emitting diode device as claimed in claim 12, wherein a polymer film adjustment layer containing the transparency adjustment particles is obtained by using transparency adjustment particles having a size smaller than half a light emission wavelength (λ/2) and a transparent polymer so that a fine pattern having a size larger than half the light emission wavelength (λ/2) is formed.

15. The light emitting diode device as claimed in claim 1, wherein the light emitting diode unit contains a gallium nitride-based compound.

16. The light emitting diode device as claimed in claim 1, wherein the light emitting diode unit is formed in a laser liftoff method.

17. The light emitting diode device as claimed in claim 1, wherein the light emitting diode unit has a p-type layer, an active layer, an n-type layer, and a transparency adjustment layer formed on top of the n-type layer.

18. A light emitting apparatus having the light emitting diode device as defined in claim 1.

19. A method for manufacturing a light emitting diode device having a transparency adjustment layer formed on a light emitting surface of a light emitting diode unit, the method comprising the steps of:
(a) applying a slurry to a substrate, the slurry containing a transparent polymer or the polymer and transparency adjustment particles;
(b) compressing a surface of the substrate, the slurry having been applied to the surface, by using a stamp having a fine pattern carved on a surface;
(c) shaping a fine pattern by means of hardening based on UV rays or heat and separating a film from the stamp, a fine pattern having been imprinted on the film; and
(d) attaching a polymer film, the fine pattern having been imprinted on the polymer film, or a film containing the polymer and the transparency adjustment particles to a light emitting surface of a light emitting diode unit.

20. A method for manufacturing a light emitting diode device having a transparency adjustment layer formed on a light emitting surface of a light emitting diode unit, the method comprising the steps of:
(a) preparing a transparent polymer substrate with or without transparency adjustment particles;
(b) compressing a surface of the substrate by using a stamp having a fine pattern carved on a surface;
(c) shaping a fine pattern by means of hardening based on UV rays or heat so that the fine pattern is imprinted on a surface of the substrate; and
(d) attaching the polymer substrate to a light emitting surface of a light emitting diode unit, the substrate having the fine pattern imprinted on the surface and containing a polymer or the polymer and the transparency adjustment particles.

21. A polymer film or substrate with or without transparency adjustment particles, comprising:
(a) a film or substrate having a fine pattern imprinted on a surface so as to adjust a surface structure of a light emitting diode unit, the film or substrate containing a polymer or the polymer and transparency adjustment particles, and
(b) a polymer film with no fine pattern or a release film removably attached to a surface of the substrate.
